(19) United States
(12) Patent Application Publication
(10) Pub. No.: US 2009/0243637 A1
(43) Pub. Date: Oct. 1, 2009

(54) MEASURING APPARATUS HAVING NANOTUBE PROBE

(75) Inventors: Makoto OKAI, Tokorozawa (JP); Motoyuki Hirooka, Hitachi (JP)

Correspondence Address: MILES & STOCKBRIDGE PC, 1751 PINNACLE DRIVE, SUITE 500, MCLEAN, VA, 22102-3833, US

(73) Assignee: HITACHI HIGH-TECHNOLOGIES CORPORATION

(21) Appl. No.: 12/412,113

(22) Filed: Mar. 26, 2009

(30) Foreign Application Priority Data
Mar. 31, 2008 (JP) 2008-089169

(51) Int. Cl. G01R 27/00

(52) U.S. Cl. 324/724; 977/742; 977/953

(57) ABSTRACT

An object of the present invention is to provide a measuring apparatus such as a conduction characteristics evaluation apparatus, a probe microscope, etc. having a nanotube probe, wherein the measuring apparatus is succeeded in reducing the electrical resistance of the carbon nanotube as well as the electrical resistance between the carbon nanotube and a metal substrate to improve electrical conduction characteristics of the nanotube probe and attain a uniform diameter, thus improving the measurement accuracy.

In order to solve the above-mentioned problem, there is provided a conduction characteristics evaluation apparatus having a nanotube probe made of a nanotube coated by tiny fragments of graphene sheets to improve the wettability with respect to metal materials and then coated by a metal layer, or a conduction characteristics evaluation apparatus having a nanotube probe made of a metal-coated amorphous nanotube composed of tiny fragments of graphene sheets.

### BACKGROUND OF THE INVENTION

1. Field of the Invention

The present invention relates to a measuring apparatus such as a conduction characteristics evaluation apparatus, a probe microscope, etc. having a probe made of a carbon nanotube.

2. Description of the Related Art

Carbon nanotubes are 0.7 nanometers to several tens of nanometers in diameter and several sub-microns to several tens of microns in length, providing a very large length-to-diameter ratio. Therefore, carbon nanotubes are promising for use as a probe for measuring electrical conduction characteristics and dimensions of a micro-figure sample. JP-A-2002-031655 describes a conduction characteristics evaluation apparatus having a probe made of a carbon nanotube.

### SUMMARY OF THE INVENTION

When a carbon nanotube is directly used as a probe as described in JP-A-2002-031655, it may be difficult to accurately measure electrical conduction characteristics because of its own electrical resistance and the contact resistance between the nanotube and a substrate. For example, when the electrical resistivity of the carbon nanotube is as high as 1×10⁻⁶ Ωm and the contact resistance between the nanotube and a metal electrode is as high as several tens of kΩ, it was difficult to evaluate electrical conduction characteristics of a sample with high accuracy.

An object of the present invention is to attain a measuring apparatus such as a conduction characteristics evaluation apparatus, a probe microscope, etc. capable of sample observation with high accuracy by using a carbon nanotube as a probe, wherein the measuring apparatus enables reduction in the electrical resistance of the carbon nanotube as well as the electrical resistance between the carbon nanotube and a metal substrate.

One possible method for reducing the electrical resistance of the probe as well as the electrical resistance between the probe and the metal substrate for fixing the probe is to provide a metal layer on the surface of the carbon nanotube. However, when the carbon nanotube is directly coated by the metal layer, it becomes difficult to form a uniform metal layer because of the low wettability between the surface of the carbon nanotube and metal materials. This causes problems such as the adherence of metal particles onto the nanotube surface, uneven surface of the metal layer, and the like. In particular, the uneven surface of the metal layer is not desirable because it causes variation in probe diameter, adversely affecting the observation of electrical conditions and the shape of a sample.

Then, the present invention is characterized in the use of a probe which comprises: a nanotube; a coating layer formed on the nanotube surface, the coating layer being composed of flake materials such as tiny fragments of graphene sheets; and a metal layer coating the coating layer. Such a coating layer can improve the wettability between the nanotube surface and metal materials, and accordingly provide uniform metal coating. This makes it possible to reduce the electrical resistance of the probe as well as the electrical resistance between the probe and the substrate for fixing the probe.

The present invention can provide a conduction characteristics measuring apparatus such as a conduction characteristics evaluation apparatus, a probe microscope, etc. capable of sample observation with high accuracy by using a carbon nanotube as a probe.

### BRIEF DESCRIPTION OF THE DRAWINGS

Other objects and advantages of the invention will become apparent from the following description of embodiments with reference to the accompanying drawings in which:

FIG. 1 is a diagram showing a probe made of a carbon nanotube (hereinafter referred to as nanotube probe) according to a first embodiment;

FIG. 2 is a diagram showing example measurement results of electrical conduction characteristics of two different carbon nanotubes;

FIG. 3 is a diagram showing a nanotube probe made of an amorphous nanotube;

FIG. 4 is a diagram showing a nanotube probe having a carbon-containing metal coating layer;

FIG. 5 is a diagram showing a nanotube probe made of a nanotube having open ends at which a metal terminal is provided;

FIG. 6 is a diagram showing a nanotube probe made of a multi-walled carbon nanotube having layers 601 with electrical connections therebetween;

FIG. 7 is a diagram showing an example configuration of a conduction characteristics evaluation apparatus having a single nanotube probe; and

FIG. 8 is a diagram showing an example configuration of a conduction characteristics evaluation apparatus having a plurality of nanotube probes.

### DETAILED DESCRIPTION OF THE PREFERRED EMBODIMENTS

Measuring apparatuses according to the present invention will be explained below in more detail.

Nanotubes are composed of sheet-like compounds having a two-dimensional structure. The sheet-like compounds have a single-layer tubular structure or multilayer coaxial tubular structure.

The following embodiments show example multi-walled carbon nanotubes having three layers composed of only carbon.

The configuration of the multi-walled carbon nanotubes is not limited to the three-layer structure, and any number of layers can be used. Further, it is also possible to use a single-walled carbon nanotube.

Both ends of the nanotubes can be either capped with a hemisphere or open.

Sheet-like substances can be fragments of graphene sheets composed of carbon or other constituent materials of the nanotubes, or BN compounds or other substances which form two-dimensional sheets. The sheet-like substances are formed through the chemical vapor deposition (CVD) method or sputtering method, or by breaking an aggregate of sheet-like substances.

In addition to nanotubes composed of only carbon, it is also possible to use carbon nanotubes containing boron or nitrogen and nanotubes composed of any elements other than carbon.

In the following embodiments, gold, platinum, and other metals having a high conductivity can be used as a metal layer. In particular, the use of gold, silver, or platinum is desirable. Although aluminum and iron can also be used, it is necessary to pay attention to oxidization. Further, metals having a tendency of forming carbide, such as tungsten, are difficult to be used as a metal layer.

One possible method for attaining a probe shape having a high conductivity and a large length-to-diameter ratio is to apply many flake sheet-like substances to the above-mentioned nanotubes to form a coating layer and then provide a metal coating layer on the coating layer. Another method for this purpose is to provide a metal coating layer on an amorphous tube composed of many flake sheets without using the above-mentioned nanotubes.

Further, the use of a carbon-containing metal coating layer also improves the wettability between the nanotube and the metal layer. The carbon-containing metal coating layer can be a film containing a carbide such as tungsten carbide (WC) and a smaller amount of carbon than metal. In particular, it is desirable that the ratio of carbon be smaller than that of the carbide to improve the conductivity of the nanotube surface.

With nanotubes composed of multiple layers, electrical conduction characteristics can be improved by utilizing internal layers instead of providing a metal layer. For example, when the ends of the nanotubes are open (not capped with a hemisphere), the conductivity can be improved by providing a metal terminal at the ends to allow electrical connections between layers. The ends of the nanotubes have no π-electron barrier and a dumpling connection is exposed, providing a good wettability with metal materials. Further, the conductivity of the multi-walled carbon nanotubes can be improved by injecting metal particles or the like between the layers.

### First Embodiment

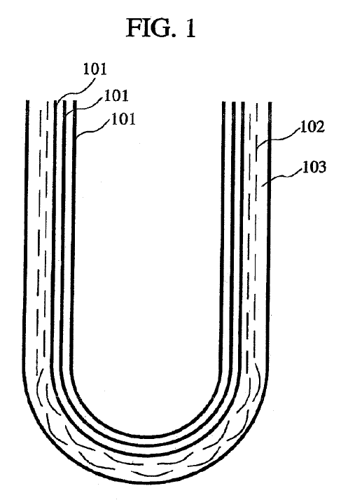

A nanotube probe according to the first embodiment will be explained below with reference to FIG. 1. The nanotube probe according to the present embodiment has a multilayer structure, comprising: a multi-walled carbon nanotube composed of a plurality of carbon layers 101; a layer of graphene sheet fragments 102 coating the surface of the multi-walled carbon nanotube; and a metal coating layer 103 formed on the surface of the layer of graphene sheet fragments 102.

The graphene sheet fragments 102 coat the carbon nanotube, each being densely stacked. The ends of each graphene sheet have an exposed terminal group, providing a better wettability with metal materials than the surface of graphene sheet. When the nanotube is densely coated by tiny fragments of graphene sheets, the nanotube surface provides a good wettability with metal materials, making it possible to stack a metal layer having little unevenness on the layer of graphene sheet fragments.

The vapor deposition method can be used to stack tiny fragments of graphene sheets on the surface of the carbon nanotube. With this method, carbon nanotubes, or carbon nanotubes bonded to a substrate or the like are put in a growth reactor and then heated to 400 to 900° C. During the heating process, carbon-containing materials such as acetylene, propylene, etc. are fed into the growth reactor. As a result, a layer of graphene sheet fragments can be formed on the surface of the carbon nanotubes. Fragments of graphene sheets are around 0.1 to 10 nanometers in size. The thickness of the layer of graphene sheet fragments can be controlled by the growth temperature and growth time.

Another method for forming the layer of graphene sheet fragments is to radiate electron ray, ion beam, laser beam, etc. while feeding the gas of carbon-containing materials. The carbon-containing gas is broken apart into tiny fragments of graphene sheets at the surface of the multi-walled carbon nanotubes by the energy of electron ray, ion beam, or laser beam. Then, the fragments of graphene sheets are stacked thereon. Further, the layer of graphene sheet fragments can be formed also through the sputtering coating method or resistance-heating coating method.

One method for forming a metal coating layer on the layer of graphene sheet fragments is to radiate electron ray, ion beam, laser beam, etc. onto the layer while feeding the gas of metal-containing materials. The sputtering coating method and the resistance-heating coating method can also be used for this purpose. Further, a metal coating layer can also be produced through the steps of: mixing a nanotube dispersion liquid and a metal nanoparticle dispersion liquid; applying the metal nanoparticles to the nanotube surface; and performing heat treatment.

Coating the carbon nanotubes with a metal layer in this way makes it possible to reduce the electrical resistivity of the carbon nanotubes to 10⁻⁸ Ωm.

This method is preferable for conductive AFM or the like since it can attain probes having good electrical conduction characteristics and a uniform shape.

### COMPARATIVE EXAMPLE

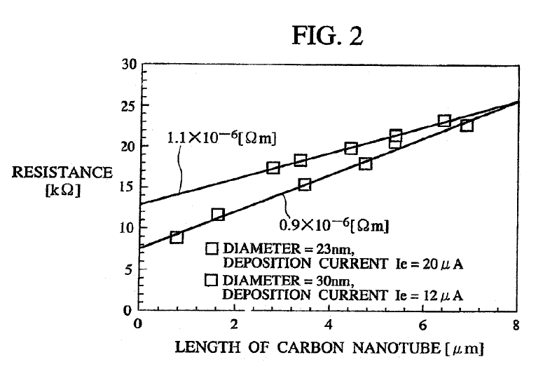

FIG. 2 is a diagram showing results of electrical conduction measurement of two different multi-walled carbon nanotubes. We performed the steps of: providing each carbon nanotube as a bridge between two IrPt needles; connecting each IrPt needle and the carbon nanotube with a tungsten electrode; and measuring the electrical resistance between the two IrPt needles. After measurement, we performed the steps of: disconnecting the carbon nanotube with an excessive current; reconnecting the cut end and an IrPt needle with a tungsten electrode; and measuring the electrical resistance between the two IrPt needles. We repeated this process to measure the dependence of the electrical resistance on the length of the carbon nanotube. The graph of FIG. 2 shows the dependence of the combined resistance on the length of the carbon nanotube. The electrical resistivity of the carbon nanotube itself can be estimated from the inclination of the graph, and the contact resistance between each IrPt needle and the carbon nanotube can be estimated from the intercept of the graph. FIG. 2 shows measurement results of two different multi-walled carbon nanotubes having a diameter of 23 and 30 nanometers. From the average of the obtained values, the electrical resistivity of the carbon nanotube is 1×10⁻⁶ Ωm, and the contact resistance between each IrPt needle and the carbon nanotube is 10 kΩ (at both ends of the carbon nanotube). Therefore, in the comparison of a nanotube probe without a metal layer, current flows only on the surface layer providing low conductivity of the probe.

Further, in the comparison of a nanotube probe made of a multi-walled carbon nanotube having a metal coating layer directly stacked thereon, the metal is granulated because of the low wettability between the surface of the multi-walled carbon nanotube and metal materials, disturbing the formation of a uniform metal coating layer.

Therefore, in the comparison of the nanotube probe having a metal layer directly formed thereon, the metal layer provides a low conductivity.

### Second Embodiment

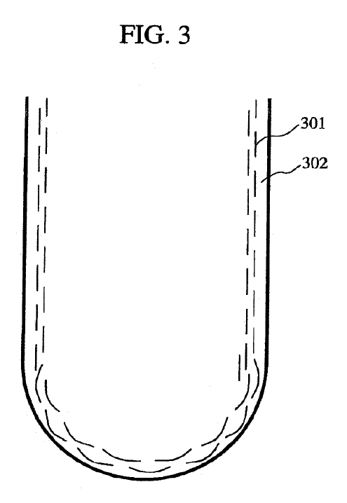

The second embodiment uses an amorphous nanotube. An example amorphous nanotube will be explained below with reference to FIG. 3. The present embodiment utilizes a carbon nanotube composed of an aggregate of fragmentary sheet-like substances (amorphous nanotube) instead of the carbon nanotubes composed of seamless sheet-like substances used in the first embodiment.

The amorphous tube is composed of tiny fragments of graphene sheets, and a metal coating layer 302 is stacked on the surface of the amorphous tube. Like the first embodiment, the surface of the amorphous tube has a good wettability with metal materials because of the effects of the terminal group of the graphene sheets. This makes it possible to stack a homogeneous metal layer on the amorphous tube composed of tiny fragments of graphene sheets.

Amorphous tubes composed of tiny fragments of graphene sheets can be produced through molding. Specifically, metal aluminum is anodized to form alumina tube holes on the surface of the metal aluminum. For example, tube holes having a diameter of 20 nm can be formed by using sulfuric acid as electrolytic solution. The depth of the tube holes is controlled by the anodization time. Tiny fragments of graphene sheets are stacked in the alumina tube holes by the vapor deposition method and then the alumina is removed through wet etching, thus obtaining amorphous tubes. With the vapor deposition method, acetylene was used as a carbon material, and tiny fragments of graphene sheets were grown at 600° C. for two hours. Further, amorphous tubes can also be produced by the ordinary vapor deposition method with which catalyst-metal-containing substances and carbon-containing substances are mixed and heated. The catalyst-metal-containing substances can be ferrocene, etc., and the carbon-containing substances can be toluene, etc. Pertinent growth temperature is 400 to 900° C.

One method for forming a metal coating layer on the layer of graphene sheet fragments is to radiate electron ray, ion beam, laser beam, etc. onto the layer while feeding the gas of metal-containing materials. The sputtering coating method and the resistance-heating coating method can also be used for this purpose.

A probe made of the above-mentioned amorphous tube and a metal coating layer makes it possible to reduce the electrical resistivity of the carbon nanotube to 10⁻⁸ Ωm.

Although the present embodiment has been explained referring to amorphous nanotubes composed of only carbon, it is also possible to use nanotubes containing boron or nitrogen or nanotubes composed of elements other than carbon. Both ends of the nanotubes can be either capped with a hemisphere or open.

### Third Embodiment

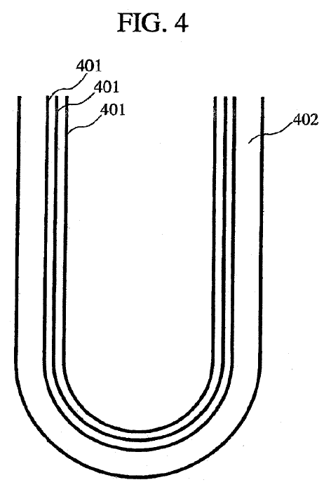

The third embodiment uses a probe made of a nanotube coated by a carbon-containing metal coating layer 402 (FIG. 4). An example probe will be explained below with reference to FIG. 4. The carbon-containing metal coating layer provides a better wettability on the surface of the carbon nanotube than a pure metal film, allowing a continuous uniform layer to be formed.

The carbon-containing metal coating layer can be formed on the surface of the multi-walled carbon nanotube by radiating electron ray, ion beam, or laser beam onto the surface while feeding the gas of metal-containing materials. As metal-containing materials, (CH₃)₃(CH₃C₅H₄)Pt, Au(CH₃)₂(CH₃COCH₂COCH₃), W(CO)₆, etc. are selected according to the metal type.

With this technique, it is also possible to form a metal layer on the carbon-containing metal coating layer, thus reducing the electrical resistivity of the carbon nanotube probe to 10⁻⁸ Ωm.

In order to improve the wettability between the metal coating layer and the nanotube, it is effective to mix at least one of constituent elements of the nanotube into the metal coating layer. This process improves not only the wettability of the metal layer with the nanotube but also the adhesion thereto, as well as the homogeneity of the metal layer.

### Fourth Embodiment

Multi-walled carbon nanotubes are composed of stacked carbon layers 401. With ordinary multi-walled carbon nanotubes, it is thought that only the outermost layer contributes to electrical conduction, since the electrical resistance between the carbon layers is larger than that in each carbon layer by at least double-figures. This means that providing electrical connections between the layers 401 of multi-walled carbon nanotubes reduces the electrical resistance by the reciprocal of the number of layers.

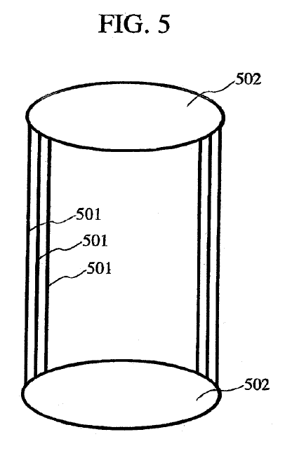

The fourth embodiment provides a metal layer 502 (FIG. 5) as a metal terminal at both ends of a multi-walled carbon nanotube to provide electrical conduction between the carbon layers. An example nanotube will be explained below with reference to FIG. 5. Since both ends of the nanotube are open, the end faces of the carbon layers are exposed thereat. With the multi-walled carbon nanotube composed of layers 501, the metal layer 502 formed at both ends of its open structure provides electrical connections between the layers 501, making it possible to remarkably reduce the electrical resistivity of the multi-walled carbon nanotube.

In order to provide the metal terminal, a metal layer is formed on a target portion by radiating electron ray, ion beam, or laser beam thereto while feeding metal-containing materials in vacuum. It is desirable to provide the thus-formed metal terminal at both ends of the nanotube.

This technique makes it possible to reduce the electrical resistivity of the carbon nanotube to 10⁻⁸ Ωm.

### Fifth Embodiment

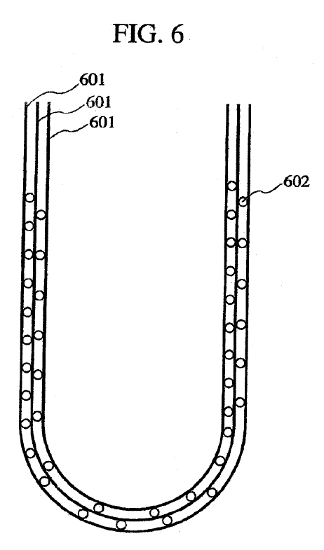

Like the fourth embodiment, the fifth embodiment provides electrical connections between layers 601 (FIG. 6) of multi-walled carbon nanotubes to reduce the electrical resistance. An example nanotube will be explained below with reference to FIG. 6. FIG. 6 shows an example carbon nanotube probe made of a multi-walled carbon nanotube containing metal atoms or metal clusters between the carbon layers. Metal atoms or metal clusters 602 are injected between the carbon layers of the multi-walled carbon nanotube to provide electrical connections between the carbon layers 601, thus remarkably reducing the electrical resistivity of the multi-walled carbon nanotube.

Metal particles can be impregnated into the nanotube through gas phase reaction. When carbon nanotubes are disposed in metal gas and then left for seven to eight hours, metal elements are injected between the carbon layers. Alloys and clusters can be injected between the layers by changing the type of metal gas.

FIG. 6 shows an example multi-walled carbon nanotube having a three-layer structure. Metal atoms or metal clusters are provided between the carbon layers. Gold, platinum, and any other metals and alloys can be used as metal atoms or metal clusters.

Although a nanotube composed of carbon layers has been explained above, carbon nanotubes containing boron, nitrogen, and any other elements can be used.

The following technique is used to inject metal atoms and metal clusters into the carbon layers. Metal atoms and metal clusters can be injected between layers of multi-walled carbon nanotubes by dispersing multi-walled carbon nanotubes in a metal-containing solution and then leaving for several hours. Further, metal atoms and metal clusters can also be injected between layers of multi-walled carbon nanotubes by enclosing multi-walled carbon nanotubes and metal-containing materials in a vacuum container and then heating it. This technique makes it possible to reduce the electrical resistivity of the carbon nanotube to 10⁻⁸ Ωm.

### Sixth Embodiment

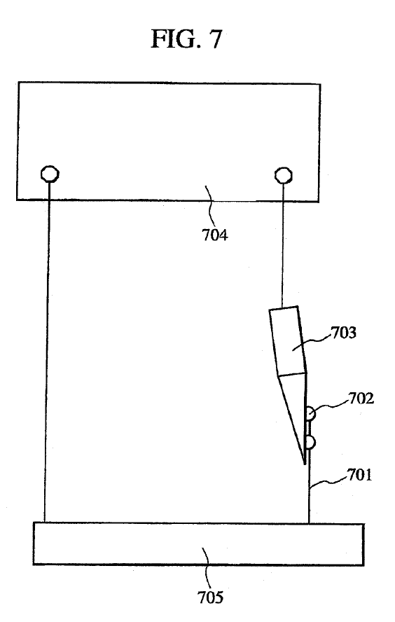

FIG. 7 is a diagram showing an example configuration of an apparatus for measuring electrical conduction characteristics of a sample (hereinafter referred to as conduction characteristics measuring apparatus or simply as measuring apparatus) The measuring apparatus according to the present embodiment uses a nanotube prober comprising a needle substrate 703 having a nanoneedle shape, and a nanotube probe 701 bonded to the needle substrate 703 with a bonding agent 702. The nanotube prober is connected to a controller 704, and the nanotube probe 701 is made in contact with the surface of a sample under measurement 705 to measure its electrical conduction characteristics. The sample is placed on a sample stand which is connected with the controller. The controller includes a power supply, an ammeter, and a control unit to control the nanotube prober and at the same time acquire information obtained when the probe comes in contact with the sample. It is possible that the sample stand and the controller may be connected to a ground.

It is desirable that measurement be performed under vacuum conditions such as the inside of an electron microscope because such measurement may be affected by vapor or the like in the atmosphere.

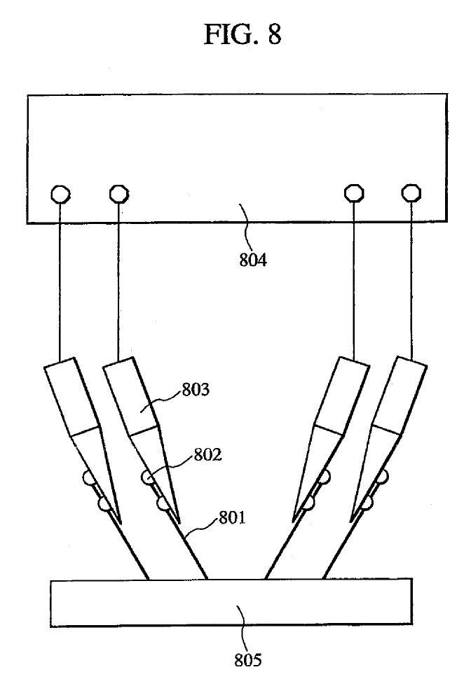

Further, the measuring apparatus may be provided with a plurality of nanotube probers. FIG. 8 shows an example configuration of a conduction characteristics measuring apparatus having four nanotube probers. Four nanotube probers 801, respectively connected to a controller 804, are made in contact with the surface of a sample under measurement 805 to measure its electrical conduction characteristics by the so-called four-terminal method.

The use of a nanotube having a coating layer and a metal layer as each nanotube probe makes it possible to reduce the contact resistance between the probe and the needle substrate to 10Ω or less. In this case, it is desirable to use a metal coating layer of tungsten, platinum, gold, etc. as an bonding agent.

During measurement, the surface shape of the sample under measurement 805 can be observed simultaneously by scanning the surface of the sample and detecting a force acting between the sample and the probe, based on the principle of atomic force microscope. Further, electron states at the surface of the sample under measurement can be measured by measuring a tunnel current flowing between the sample and the probe, based on the principle of scanning tunneling microscope.

While the invention has been described in its preferred embodiments, it is to be understood that the words which have been used are words of description rather than limitation and that changes within the purview of the appended claims may be made without departing from the true scope and spirit of the invention in its broader aspects.

### FIG. 2

Resistance [kΩ]
Diameter=23 nm, Deposition current Ie=20 μA
Diameter=30 nm, Deposition current Ie=12 μA
Length of carbon nanotube [μm]

What is claimed is:

1. A conduction characteristics measuring apparatus having a nanotube-based probe for sample observation,
wherein the probe comprises:
a nanotube;
a sheet layer composed of flake materials for coating the nanotube; and
a metal layer for coating the sheet layer.

2. The conduction characteristics measuring apparatus according to claim 1,
wherein at least one of constituent elements of the nanotube is contained in the sheet layer.

3. The conduction characteristics measuring apparatus according to claim 1,
wherein the sheet layer is a layer formed by the vapor deposition method.

4. The conduction characteristics measuring apparatus according to claim 1,
wherein the sheet layer contains at least one of constituent elements of the nanotube.

5. The conduction characteristics measuring apparatus according to claim 1,
wherein the sheet layer is formed by the vapor deposition method.

6. A conduction characteristics measuring apparatus having a nanotube-based probe for sample observation,
wherein the nanotube has a multilayer coaxial tubular structure having an opening at both ends; and
wherein the nanotube is provided with a conductive metal portion at both ends.

7. The conduction characteristics measuring apparatus according to claim 6,
wherein the nanotube has a multilayer coaxial tubular structure having an opening at both ends; and
wherein the nanotube contains metal atoms or metal clusters between the sheet-like substances constituting the nanotube.

8. A conduction characteristics measuring apparatus having a nanotube-based probe for sample observation,
wherein the probe comprises:
a nanotube formed by stacked sheet-like substances; and
a metal layer coating the nanotube.

9. The conduction characteristics measuring apparatus according to claim 8,
wherein the nanotube is formed by the vapor deposition method.
